(19) United States
(12) Patent Application Publication
(10) Pub. No.: US 2012/0268894 A1
(43) Pub. Date: Oct. 25, 2012

(54) SOCKET AND HEAT SINK UNIT FOR USE WITH REMOVABLE LED LIGHT MODULE

(75) Inventors: Clayton Alexander, Westlake Village, CA (US); Robert Rippey, III, Newbury Park, CA (US)

(73) Assignee: JOURNEE LIGHTING, INC., Westlake Village, CA (US)

(21) Appl. No.: 13/454,453

(22) Filed: Apr. 24, 2012

Related U.S. Application Data
(60) Provisional application No. 61/478,564, filed on Apr. 25, 2011.

(51) Int. Cl. H05K 7/20; B21D 53/02

(52) U.S. Cl. 361/709; 29/890.03

(57) ABSTRACT

A socket and heat sink unit for use with a removable LED light module includes separate socket and heat sink portions that are coupleable to each other. The socket can releasably couple to a removable LED light module. The heat sink can couple to the socket and extends about a central axis. The heat sink includes a plurality of fin members that extend outward from a central core portion. At least two adjacent fin members define a channel therebetween at the junction of the fin members to the central core portion. The channel can receive a fastener therein to couple the socket to the heat sink. An extrusion process can be used to manufacture the heat sink portion, and to form one or more fastener holes in the heat sink portion sized to receive one or more fasteners to fasten the heat sink portion to the socket portion.

### CLAIM FOR PRIORITY

The present application claims priority to U.S. Provisional Patent Application No. 61/478,564, filed Apr. 25, 2011, the entire contents of which are hereby incorporated by reference and should be considered a part of this specification.

### BACKGROUND

1. Field

The present invention is directed to a socket and heat sink unit for an LED light fixture, and more particularly to a replaceable socket and heat sink unit for use with a removable LED light module, and a method for making the same.

2. Description of the Related Art

Light fixture assemblies such as lamps, ceiling lights, and track lights are important fixtures in many homes and places of business. Such assemblies are used not only to illuminate an area, but often also to serve as a part of the decor of the area. However, it is often difficult to combine both form and function into a light fixture assembly without compromising one or the other.

Traditional light fixture assemblies typically use incandescent bulbs. Incandescent bulbs, while inexpensive, are not energy efficient, and have a poor luminous efficiency. To address the shortcomings of incandescent bulbs, a move is being made to use more energy-efficient and longer lasting sources of illumination, such as fluorescent bulbs, high-intensity discharge (HID) bulbs, and light emitting diodes (LEDs). Fluorescent bulbs and HID bulbs require a ballast to regulate the flow of power through the bulb, and thus can be difficult to incorporate into a standard light fixture assembly. Accordingly, LEDs, formerly reserved for special applications, are increasingly being considered as a light source for more conventional light fixtures assemblies.

LEDs offer a number of advantages over incandescent, fluorescent, and HID bulbs. For example, LEDs produce more light per watt than incandescent bulbs, LEDs do not change their color of illumination when dimmed, and LEDs can be constructed inside solid cases to provide increased protection and durability. LEDs also have an extremely long life span when conservatively run, sometimes over 100,000 hours, which is twice as long as the best fluorescent and HID bulbs and twenty times longer than the best incandescent bulbs. Moreover, LEDs generally fail by a gradual dimming over time, rather than abruptly burning out, as do incandescent, fluorescent, and HID bulbs. LEDs are also desirable over fluorescent bulbs due to their decreased size and lack of need of a ballast, and can be mass produced to be very small and easily mounted onto printed circuit boards.

While LEDs have various advantages over incandescent, fluorescent, and HID bulbs, the widespread adoption of LEDs has been hindered by the challenge of how to properly manage and disperse the heat that LEDs emit. The performance of an LED often depends on the ambient temperature of the operating environment, such that operating an LED in an environment having a moderately high ambient temperature can result in overheating the LED, and premature failure of the LED. Moreover, operation of an LED for extended period of time at an intensity sufficient to fully illuminate an area may also cause an LED to overheat and prematurely fail.

Accordingly, high-output LEDs require direct thermal coupling to a heat sink device in order to achieve the advertised life expectancies from LED manufacturers. This often results in the creation of a light fixture assembly that is not upgadeable or replaceable within a given light fixture. For example, LEDs are traditionally permanently coupled to a heat-dissipating fixture housing, requiring the end-user to discard the entire assembly after the end of the LED's lifespan.

Accordingly, there is a need for a socket and heat sink unit that can couple to a removable LED light module and can be easily incorporated in a variety of light fixtures, and for methods of manufacturing the same.

### SUMMARY

In accordance with one embodiment, a socket and heat sink unit for use with a removable LED light module is provided. The unit includes a socket configured to releasably couple to a removable LED light module. The unit further includes a heat sink coupleable to the socket and extending about a central axis. The heat sink portion comprises a plurality of fin members that extend outward from a central core portion. The heat sink defines one or more channels outward from the core potion and alignable with openings on the socket, the one or more channels configured to receive a fastener therein to couple the socket to the heat sink.

In accordance with another embodiment, a method for making a socket and heat sink unit coupleable to a removable LED light module is provided. The method comprises extruding a heat sink portion extending about a central axis, the heat sink portion comprising a plurality of fin members that extend outward from a central core portion, the heat sink portion further comprising one or more channels outward from the core portion and configured to receive one or more fasteners therein. The method further comprises forming a socket portion having one or more openings alignable with the one or more channels in the heat sink portion for receiving the one or more fasteners therethrough, the socket configured to releasably couple to a removable LED light module. The method additionally comprises removably coupling the socket portion to the heat sink portion with the one or more fasteners. In some embodiments, the method further comprises coupling an LED light module to the socket such that a bottom surface of the LED light module resiliently contacts a top surface of the central core portion of the heat sink.

In accordance with another embodiment, a method for making a socket and heat sink unit coupleable to a removable LED light module is provided. The method comprises extruding a heat sink portion extending about a central axis, the heat sink portion comprising a plurality of fin members that extend outward from a central core portion, said extrusion forming one or more fastener holes in the heat sink portion configured to receive one or more fasteners therein. The method further comprises forming a socket portion having at least one opening for receiving the one or more fasteners therethrough, the socket configured to releasably couple to a removable LED light module. The method additionally comprises removably coupling the socket portion to the heat sink portion with the one or more fasteners. In some embodiments, the method further comprises extruding the heat sink portion so that at least one of the one or more fastener holes is formed in the central core portion of the heat sink portion.

### BRIEF DESCRIPTION OF THE DRAWINGS

FIG. 1 is a schematic perspective top view of one embodiment of a socket and heat sink unit.

FIG. 2 is another schematic perspective top view of the socket and heat sink unit of FIG. 1.

FIG. 3 is a schematic perspective bottom view of the socket and heat sink unit in FIG. 1.

FIG. 4 is a schematic perspective top exploded view of the socket and heat sink unit in FIG. 1.

FIG. 5 is a schematic perspective bottom exploded view of the socket and heat sink unit in FIG. 1.

FIG. 6 is a schematic exploded view of the socket and heat sink unit of FIG. 1 with one embodiment of an LED light module coupleable to the socket.

FIG. 7 is a schematic assembled view of the socket and heat sink unit of FIG. 1 with the LED light module of FIG. 6.

FIG. 8 is a schematic top or bottom view of the heat sink of FIG. 1.

FIG. 8A is a schematic top or bottom view of another embodiment of a heat sink.

FIG. 9 is a schematic perspective top view of another embodiment of a socket and heat sink unit.

FIG. 10 is a schematic perspective exploded view of the socket and heat sink unit in FIG. 9.

FIG. 11 is a schematic perspective top view of the heat sink of FIG. 9.

FIG. 12 is a schematic perspective bottom view of the heat sink of FIG. 9.

### DETAILED DESCRIPTION

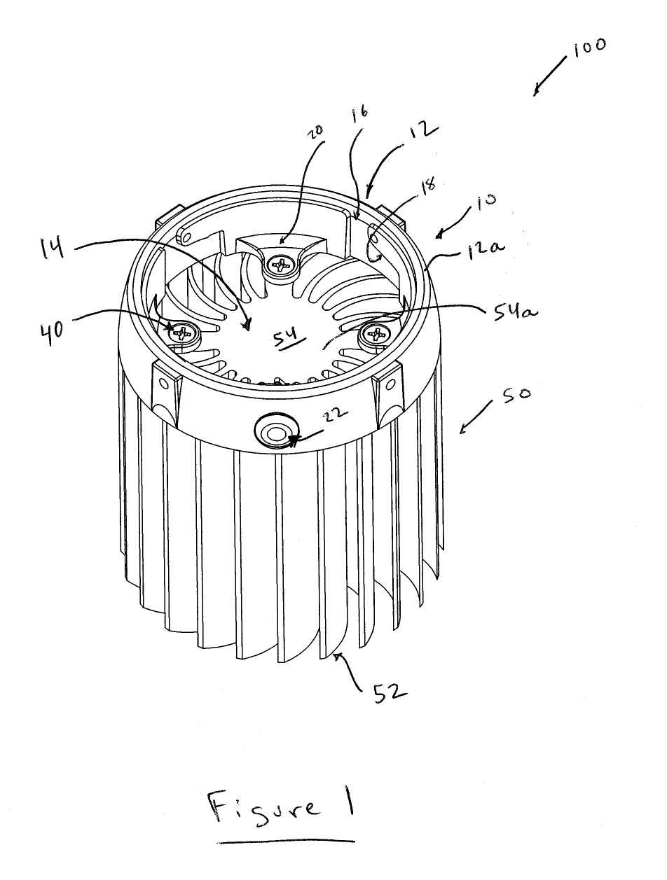

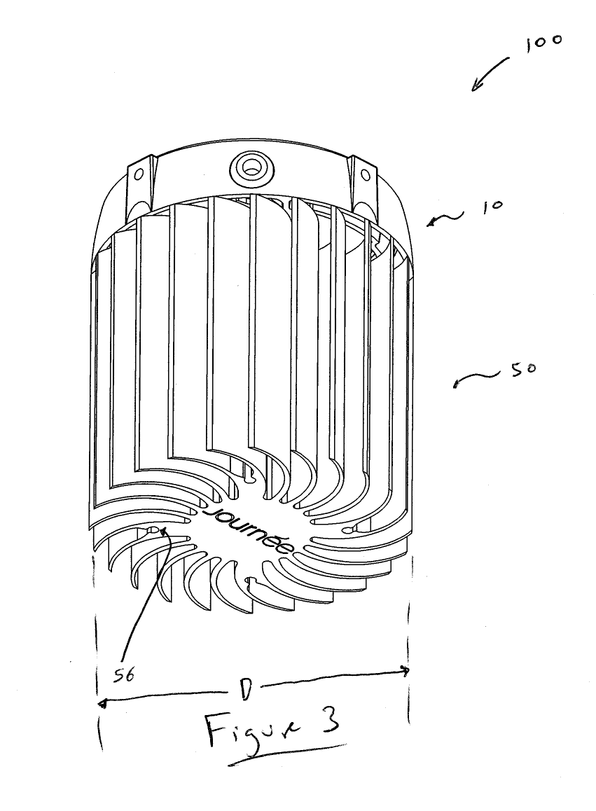

FIGS. 1-8 depict one embodiment of a socket and heat sink unit 100 for use with a removable LED light module.

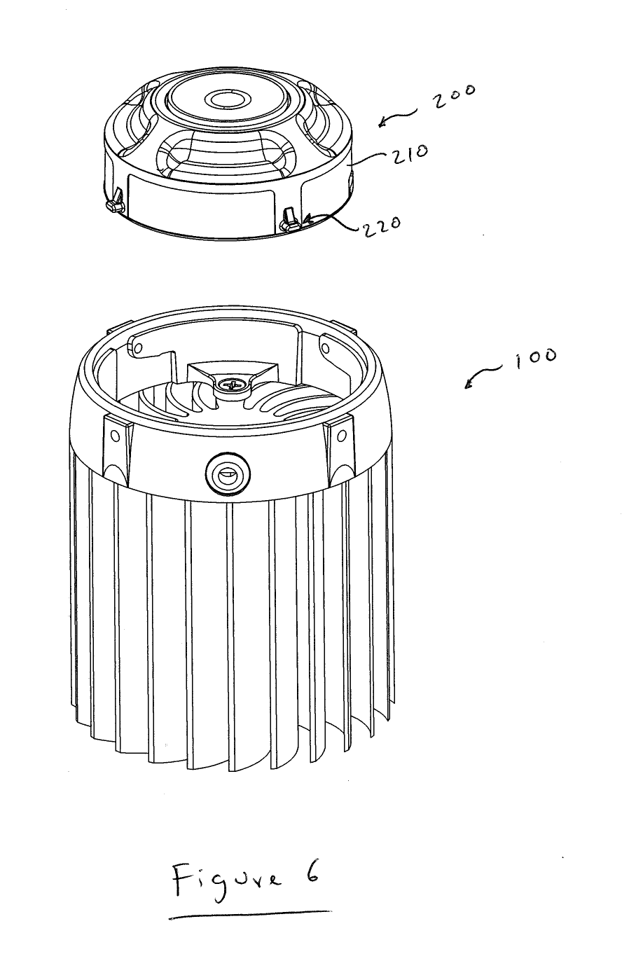

The unit 100 includes a holder or socket 10 at a proximal end and a heat sink 50 at a distal end thereof, where the socket 10 and heat sink 50 extend along a longitudinal central axis X. In the illustrated embodiment, the socket 10 and heat sink 50 are separate components that can be coupled together via one or more fasteners 40. As used herein, “socket” refers to a holder to which a removable LED light module, such as the LED light module 200 (see FIG. 6), couples and is not limited to any particular shape.

The socket 10 preferably includes a wall 12 that can define a periphery of the socket 10. In the illustrated embodiment, the wall 12 defines a continuous circumference of the socket 10. In another embodiment, the wall 12 can define the circumference of the socket 10 but be discontinuous.

In one embodiment, the wall 12 defines a central opening 14 and can include one or more recessed portions 16 formed on an inner surface of the circumferential wall 12. In one embodiment, the socket 10 has four recessed portions 16 on the inner surface of the wall 12. However, the wall can have fewer or more recessed portions 16. Preferably, the number of recessed portions 16 (or locking ramps) corresponds to a number of coupling members (e.g., protrusions or tabs) 220 on a removable LED light module 200 (see FIG. 6) that fix the LED light module 200 relative to the socket 10. However, in another embodiment, the number of recesses 16 of the socket 10 can be different than the number of coupling members of the LED light module. As shown in FIG. 6, such coupling members 220 of the LED light module 200 can be formed on an outer surface of the LED light module housing and extend radially from an outer housing 210 of the LED light module 200.

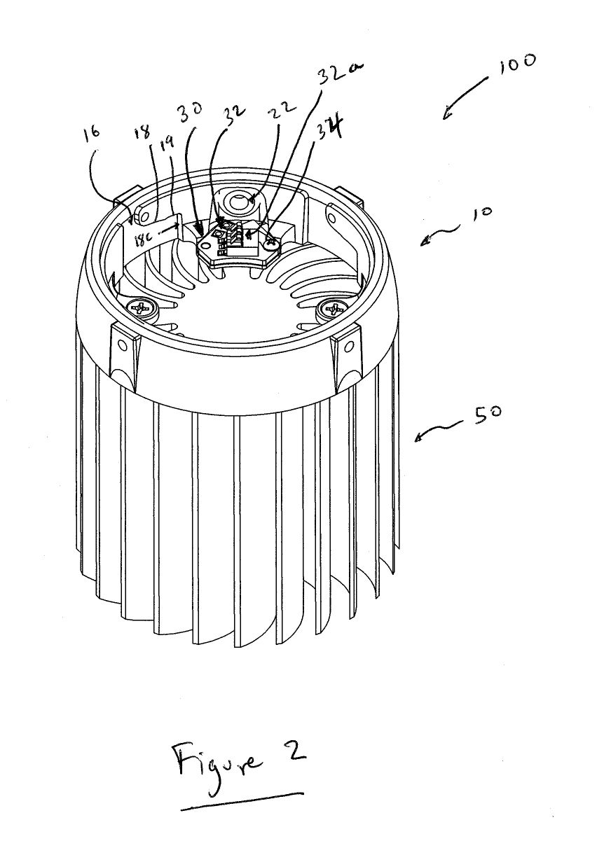

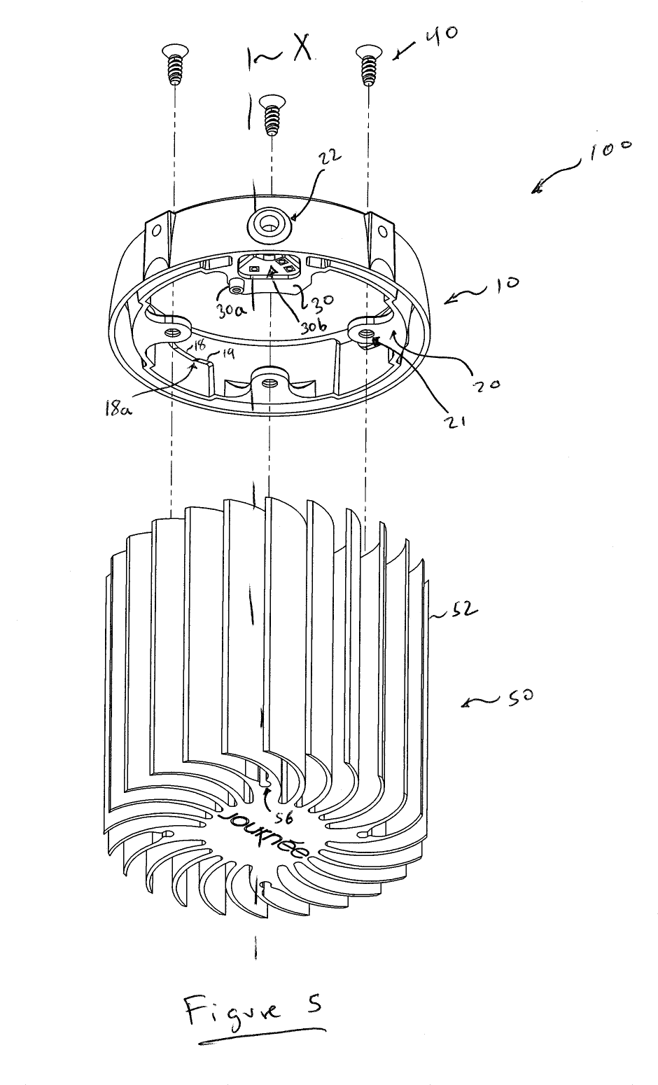

The recessed portion 16 can define an opening proximate a rim 12a of the socket 10 through which the coupling members 220 of the removable LED light module 200 extends. A user can then rotate the removable LED light module 200 relative to the socket 10 so that the coupling members 220 of the LED light module 200 move within a horizontal portion or the recessed portion 16 and along an underside edge 18, which in one embodiment can be generally horizontal. The user can continue to rotate the LED light module 200 until the coupling members 220 contacts the stop portion 18c of the recessed portion 16 to thereby couple the LED light module 200 to the socket 10. However, the LED light module 200 can be removably coupled to the socket 10 via other suitable mechanisms (e.g., brackets, press-fit connection, threads, etc.). As best shown in FIGS. 2 and 5, an edge portion 19 can be recessed relative to the underside edge 18, where the underside edge 18 transitions to the recessed edge portion 19 via an inflection or transition 18a.

The socket 10 can include one or more mounting tabs 20 via which the socket 10 can be removably coupled to the heat sink 50. In the illustrated embodiment, the socket 10 includes three mounting tabs 20. However, the socket 10 can have fewer or more mounting tabs 20. The socket 10 can be removably coupled to the heat sink 50 with one or more fasteners 40 that extend through openings 21 in the mounting tabs 20. In the illustrated embodiment, the fasteners 40 are screws, such as self-tapping screws. However, other suitable fasteners can be used to removably couple the socket 10 to the heat sink 50 (e.g. press-fit pins, etc.).

With continued reference to FIGS. 2 and 5, the socket 10 can have a raised portion 30 to which a terminal block 32 with one or more electrical contacts 32a can be fastened. For example, the terminal block 32 can be attached to the raised portion 30 with one or more fasteners 34 (e.g., screws, bolts, pins) inserted through corresponding one or more openings 30a in the raised portion 30. Advantageously, the terminal block 32 can removably connect to an electrical contact (not shown) on the removable LED light module 200 (see FIG. 6) when the LED light module 200 is coupled to the socket 10. The wall 12 can include one or more apertures 22 formed therethrough. In one embodiment, an electrical cord (not shown) for the terminal block 32 can extend through the one or more apertures 22 in the wall 12. In another embodiment, the electrical cord for the terminal block 32 can extend through an aperture 30b in the raised portion 30.

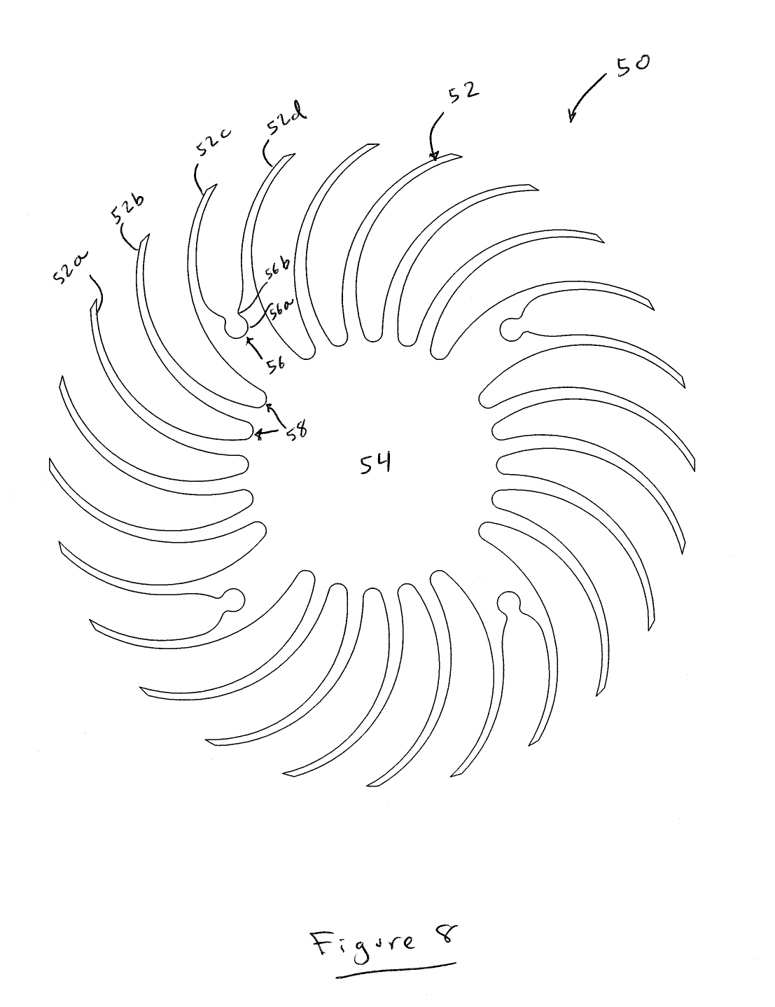

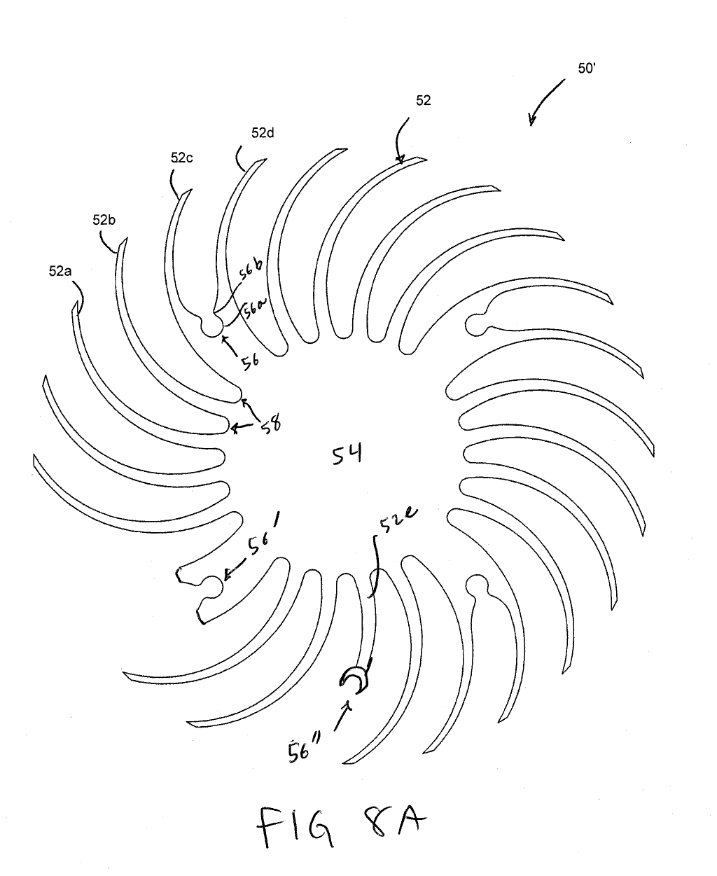

With reference to FIGS. 1-8, the heat sink 50 extends along a length L and diameter D and has a generally cylindrical shape. In one embodiment, the outer diameter D of the heat sink 50 can be generally equal to the outer diameter of the wall 12 of the socket 10. In another embodiment, the outer diameter D of the heat sink 50 can be different than the outer diameter of the wall 12 of the socket 10. The heat sink 50 can include a plurality of fin members 52 that extend outward from a central core portion 54 to the outer edge of the heat sink 50 that defines said outer diameter D. Additionally, in the illustrated embodiment, the fin members 52 extend along the entire length L of the heat sink 50. In the illustrated embodiment, the fin members 52 have a curved profile (see FIG. 8), so that the fin members 52 curve in a clockwise direction as they extend from the core portion 54. In another embodiment, the fin members 52 can curve in a counter-clockwise direction as they extend from the core portion 54.

With continued reference to FIG. 8, the fin members 52 can include a first fin member 52a and an adjacent second fin member 52b that join to the central core portion 54 at a transition 58. In the illustrated embodiment, the transition 58 has a generally U-shaped profile defined between an inner surface of the first fin member 52a and an outer surface of the second fin member 52b. However, in other embodiments, the transition 58 can have other suitable profiles (e.g., oval, square, circular). The fin members 52a, 52b can have a thickness of between about 0.03″ and 0.06″ at their outer end, and a thickness of between about 0.05″ and about 0.10″ at their inner end.

The fin members 52 can also include a third fin member 52c and an adjacent fourth fin member 52d that join to each other via a transition 56. In the illustrate embodiment, the transition 56 is located further radially outward from the central core portion 54 than the transition 58 between the first and second fin members 52a, 52b. The transition 56 includes a fastener hole 56a at least partially defined by a neck portion 56b between the third and fourth fin members 52c, 52d, wherein the distance between the third and fourth fin members 52c, 52d at the neck portion 56b is less than the distance between the fin members 52c, 52d in the fastener hole 56a and at an outer radial location of the fin members 52c, 52d. In one embodiment, the transitions 56, 58 extend along the entire length of the heat sink 50.

FIG. 8A shows another embodiment of the heat sink 50′. In the illustrated embodiment, the heat sink 50′ can have one or more transitions or extrusion openings 56′ that are independent of any fins. Additionally, the heat sink 50′ can have one or more transitions or extrusion openings 56″ at the end of a fifth fin member 52e. Though in the illustrated embodiment the heat sink 50′ has one or more transitions 56 between adjacent fins 52c, 52d, one or more transitions 56′ independent of fins, and one or more transitions 56″ at the distal end of a fin 52e, one of ordinary skill in the art will recognize that the heat sink can have only transitions 56, or only transitions 56′, or only transitions 56″ and still fall within the scope of the invention. Additionally, the heat sink 50, 50′ can have any combination of the transitions 56, 56′, 56″ and still fall within the scope of the invention. In the illustrated embodiment, the transitions or extrusion openings 56, 56′, 56″ can be generally “C” shaped. However, in another embodiment, the transitions or extrusion openings 56, 56′, 56″ can have other suitable shapes, such as circular, oval or generally curved.

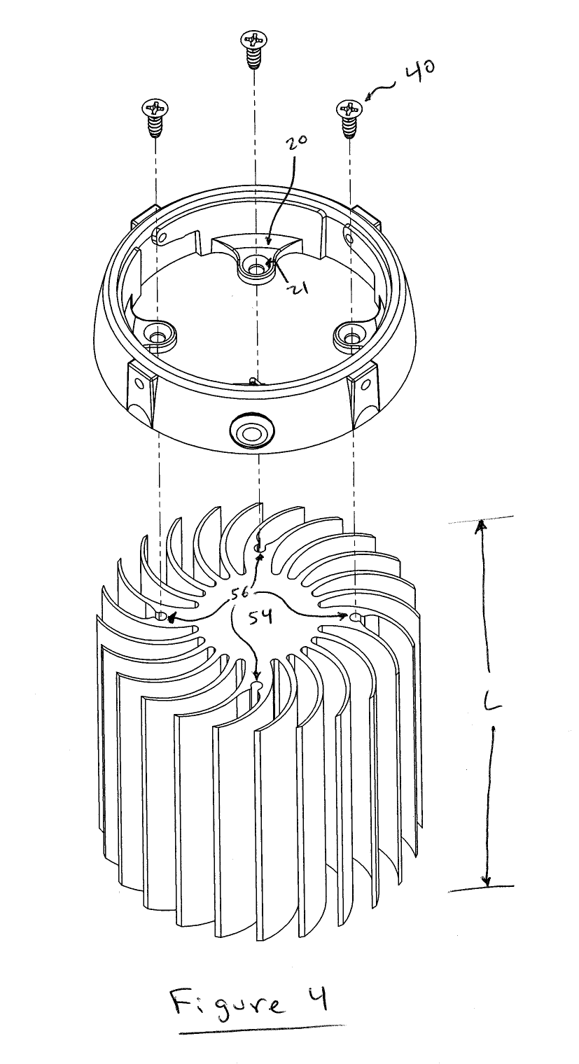

As best shown in FIG. 4, the transitions 56, as well as transitions 56′, 56″ in FIG. 8A, are sized to receive the fasteners 40 therein, to thereby couple the socket 10 to the heat sink 50. In one embodiment, the fastener hole 56a of the transition 56 can have a circular profile with a diameter of about ⅛ inch. However, in other embodiments the fastener hole 56a can have a smaller or larger diameter than this. Advantageously the fastener holes 56a need not be threaded, and can receive self-tapping screws to threadably couple the socket 10 to the heat sink 50. The fin members 52c, 52d can have a thickness of between about 0.03″ and 0.06″ at their outer end, and a thickness of between about 0.05″ and about 0.10″ at their inner end. In the illustrated embodiment, the fastener hole 56a has a generally circular profile. However, in another embodiment, the fastener hole 56a can have other suitable configurations (e.g., oval, square, etc.).

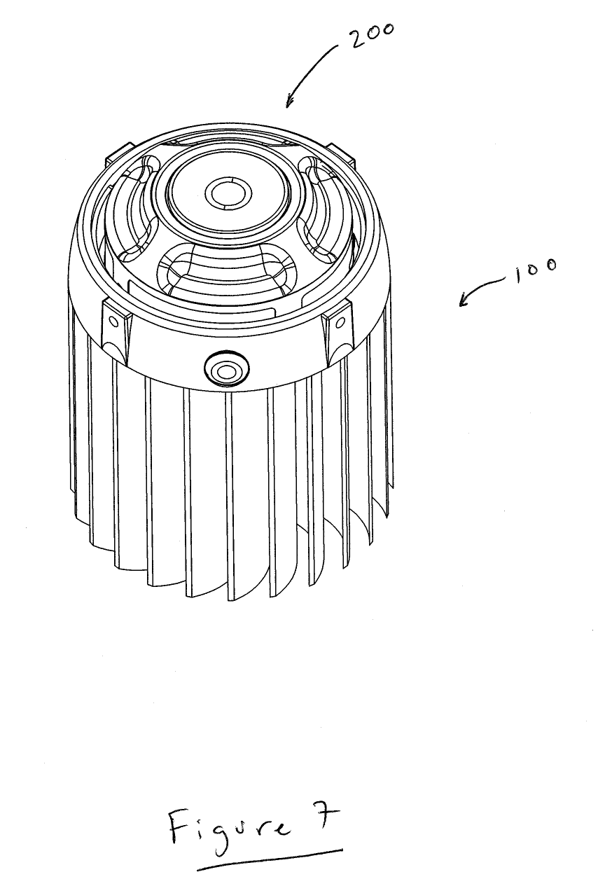

With reference to FIGS. 6-7, once the socket and heat sink unit 100 is assembled, the LED light module 200 can be removably coupled to the socket 10, as discussed above. The LED light module 200 can have a bottom surface (not shown) that resiliently contacts an end surface 54a of the central core portion 54 of the hoot sink 50, thereby allowing heat generated by the LED to be transferred from the LED light module 200 to the central core portion 54 via conduction heat transfer, and dissipated by the fin members 52 to the environment (e.g., via convection heat transfer). In another embodiment, the bottom surface of the LED light module 200 resiliently contacts a base surface (not shown) of the socket when the LED light module 200 is coupled to the socket, where the base surface is in contact with the end surface 54a of the central core portion 54 of the heat sink 50.

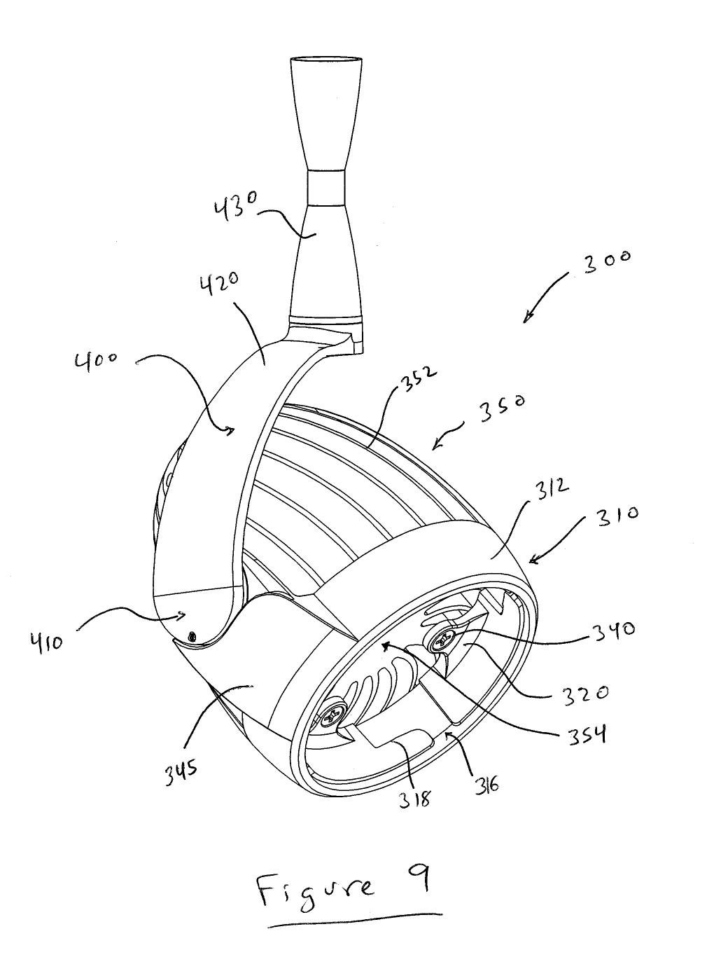

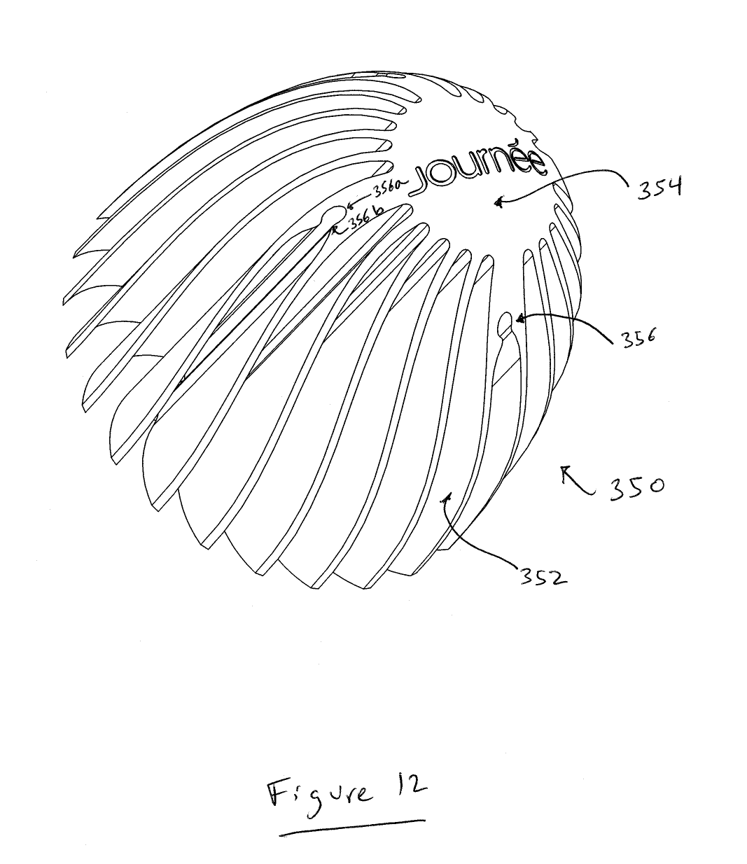

FIGS. 9-16 show another embodiment of a socket and heat sink unit 300. The unit 300 has some similar features as the unit 100, except as noted below. Thus, the reference numerals used to designate the various components or features of the unit 300 are identical to those used for identifying the corresponding components of the unit 100, except that a “3” has been added to the reference numerals, so that the description above for said components or features in connection with the unit 100 also apply to the same components or features in the unit 300.

In the illustrated embodiment, the socket and heat sink unit 300 includes a holder or socket 310 and a heat sink 350 that extend about a central axis X′. The socket 310 has a similar structure as the socket 10 described above. In addition, the socket 310 includes an arm support 345 attached to the wall 312, which couples to an attachment portion 410 of an arm 400 used to attach the socket and heat sink unit 300 to, for example, a track or a support surface (e.g., ceiling). The arm 400 includes a curved portion 420 that extends between the attachment portion 410 and a generally vertical hanging portion 430, where the hanging portion 430 can be removably coupled to the support surface (not shown).

The socket 310 has recess portions 316 that define underside edges 318, and mounting tabs 320 with openings 321 that receive fasteners 340 to couple the socket 310 to the heat sink 350.

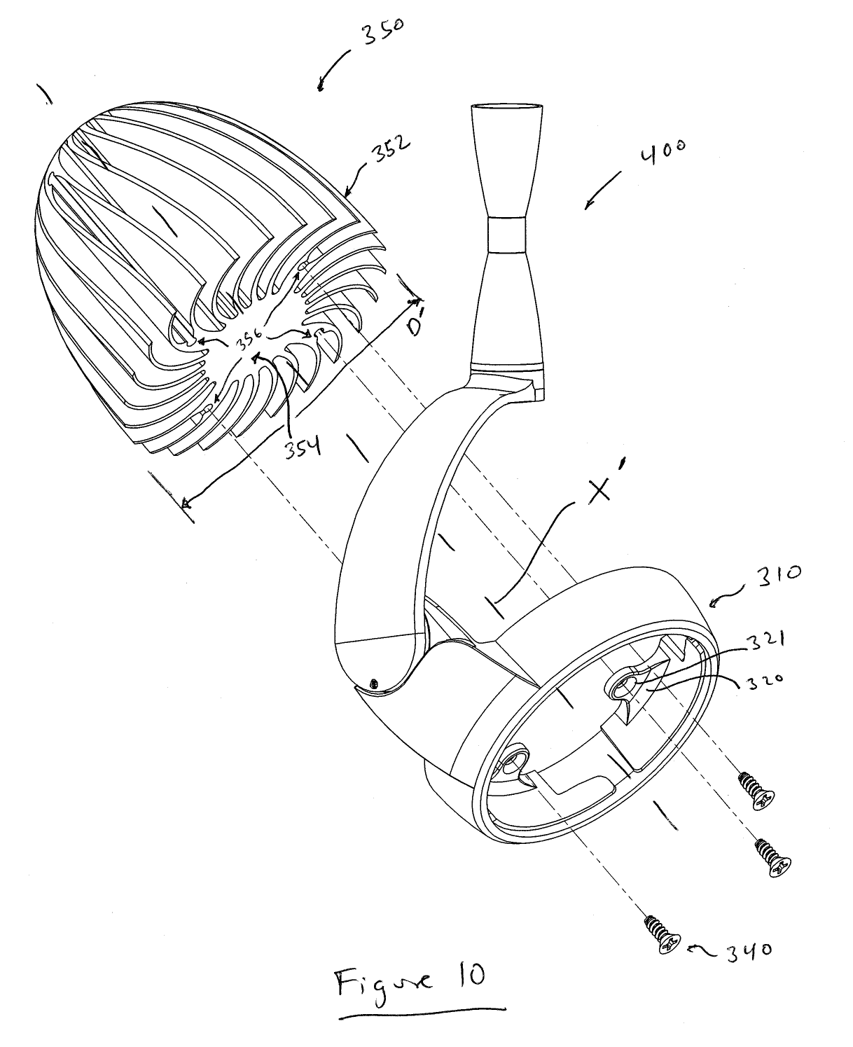

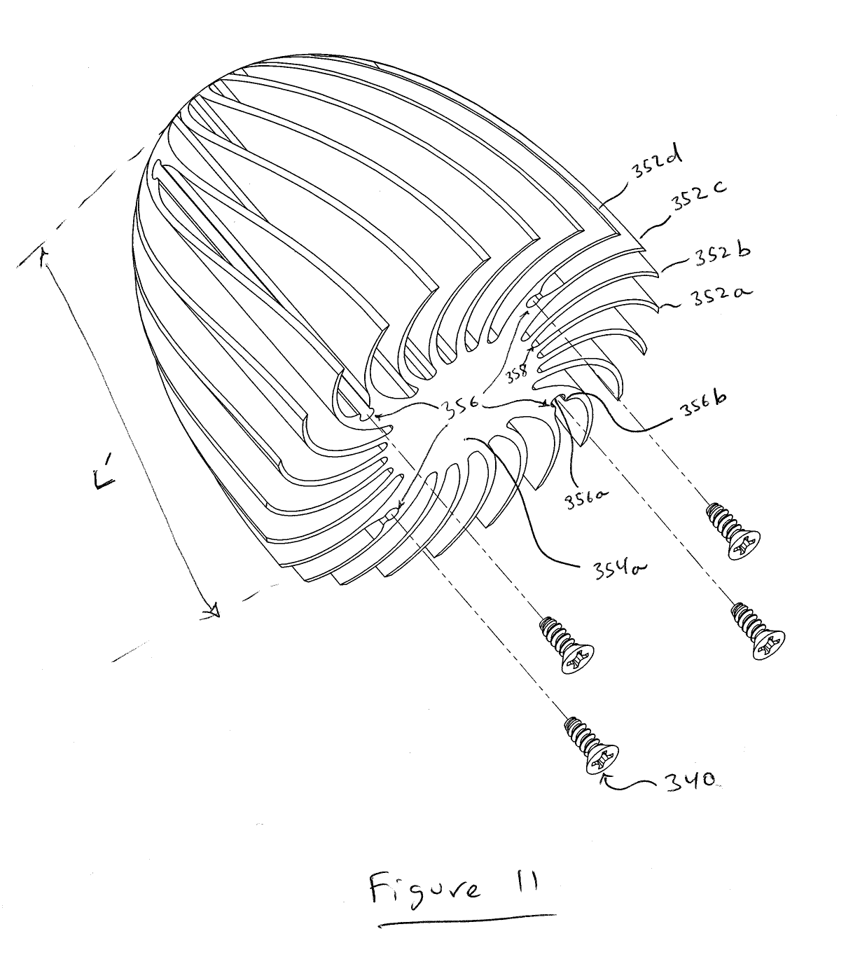

With reference FIGS. 10-12, the heat sink 350 extends along a length L′, has a maximum outer diameter D′ and has a generally domed shape. In one embodiment, the maximum outer diameter D′ of the heat sink 350 can be generally equal to the outer diameter of the wall 312 of the socket 310. In another embodiment, the maximum outer diameter D′ of the heat sink 350 can be different than the outer diameter of the wall 312 of the stcket 310. The heat sink 350 can include a plurality of fin members 352 that extend outward from a central core portion 354 to the outer edge of the heat sink 350. Additionally, the fin members 352 extend along generally the length L′ of the heat sink 350. In the illustrated embodiment, the fin members 352 have a curved profile (see FIG. 11), so that the fin members 352 curve in a clockwise direction as they extend from the central core portion 354. In another embodiment, the fin members 352 can curve in a counter-clockwise direction as they extend from the central core portion 354.

With continued reference to FIGS. 10-12, the fin members 352 can include a first fin member 352a and an adjacent second fin member 352b that join to the central core portion 354 at a transition 358. In the illustrated embodiment, the transition 358 has a generally U-shaped profile defined between an inner surface of the first fin member 352a and an outer surface of the second fin member 352b. However, in other embodiments, the transition 358 can have other suitable profiles (e.g., oval, square, circular). The fin members 352a, 352b can have a thickness of between about 0.03″ and 0.06″ at their outer end, and a thickness of between about 0.05″ and about 0.10″ at their inner end.

The fin members 352 can also include a third fin member 352c and an adjacent fourth fin member 352d that join to each other via a transition 356. In the illustrate embodiment, the transition 356 is located further radially outward from the central core portion 354 than the transition 358 between the first and second fin members 352a, 352b. The transition 356 includes a fastener hole 356a at least partially defined by a neck portion 356b between the third and fourth fin members 352c, 352d, wherein the distance between the third and fourth fin members 352c, 352d at the neck portion 356b is less than the distance between the fin members 352c, 352d in the fastener hole 356a and at an outer radial location of the fin members 352c, 352d. In one embodiment, the transitions 356, 358 extend along substantially the entire length L′ of the heat sink 350.

As best shown in FIG. 11, the transitions 356 are sized to receive the fasteners 340 therein, to thereby couple the socket 310 to the heat sink 350. In one embodiment, the fastener hole 3 56a of the transition 356 can have a generally circular configuration with a diameter of about ⅛ inch. However, in other embodiments the fastener hole 356a can have a smaller or larger diameter than this. Advantageously the fastener holes 356a need not be threaded, and can receive self-tapping screws to threadably couple the socket 310 to the heat sink 350. The fin members 352c, 352d can have a thickness of between about 0.03″ and 0.06″ at their outer end, and a thickness of between about 0.05″ and about 0.10″ at their inner end. In the illustrated embodiment, the fastener hole 356a has a generally circular profile. However, in another embodiment, the fastener hole 356a can have other suitable configurations (e.g., oval, square, etc.).

In one embodiment, the heat sink 50, 350 is manufactured using an extrusion process using an extrusion die (not shown) with a shape suitable for producing the shape of the heat sink 50, 350. Accordingly, the extrusion die can advantageously be used to manufacture a one piece heat sink 50, 350, including all the features (e.g., fin members 52, 352, transitions 56, 356 and 58, 358, fastener holes 56a, 356a, etc.) discussed above, including those needed to couple the socket 10, 310 to the heat sink 50, 350 without additional machining. In one embodiment, the extrusion process can be used to form a fastener hole (not shown) through a portion of the heat sink 50, 350 in addition to, or instead of, the fastener holes 56a, 356a. Said fastener hole can be sized to receive a fastener therein (e.g., a self-tapping screw, a press-fit pin, etc.) to fasten the socket 10, 310 to the heat sink 50, 350. In another embodiment, said fastener hole can be tapped to form threads in the hole, and the tapped fastener hole can then receive a threaded fastener therein.

In one embodiment, the heat sink 50, 350 is made of a thermally conductive material, so that the heat sink operates as a heat dissipating member when coupled to the LED light module 200 to dissipate heat generated by the LED of the LED light module. In one embodiment, the heat sink 50, 350 can be made of metal (e.g., aluminum). In another embodiment, the heat sink 50, 350 can be made of thermally conductive plastic. The socket 10, 310, in one embodiment, can be manufactured using a die cast process of a similar material as the heat sink 50, 350. In another embodiment, the socket 10, 310 can be manufactured of a different material than the heat sink 50, 350 (e.g. injection molded plastic). However, the socket 10, 310 can be manufactured using other suitable methods (e.g., machining).

An LED light module, such as the LED light module 200, can be coupled to the socket 310 of the socket and heat sink unit 300 in a similar manner as described above in connection with the socket and heat sink unit 100. In one embodiment, the LED light module 200 couples to the socket 310 such that a bottom surface of the LED light module 200 resiliently contacts an end surface 354a of the central core portion 354 of the heat sink 350.

Advantageously, said extrusion process allows the heat sink 50, 350 to be manufactured in an efficient and cost effective manner without requiring any additional machining to create features for attaching the socket to the heat sink, thus resulting in less cost and time for manufacturing the unit 100, 300. Additionally, forming the fastener holes 56a, 356a of the transitions 56, 356 using the extrusion process, advantageously reduces the cost of assembly for the socket and heat sink unit 100, 300, as holes do not need to be drilled in the heat sink 50, 350 and tapped to create a threaded surface for coupling with corresponding screws. Rather, the fastener holes 56a, 356a can receive self-tapping screws to easily couple the socket 10, 310 to the heat sink 50, 350.

Of course, the foregoing description is that of certain features, aspects and advantages of the present invention, to which various changes and modifications can be made without departing from the spirit and scope of the present invention. Moreover, the socket and heat sink unit need not feature all of the objects, advantages, features and aspects discussed above. Thus, for example, those of skill in the art will recognize that the invention can be embodied or carried out in a manner that achieves or optimizes one advantage or a group of advantages as taught herein without necessarily achieving other objects or advantages as may be taught or suggested herein. In addition, while a number of variations of the invention have been shown and described in detail, other modifications and methods of use, which are within the scope of this invention, will be readily apparent to those of skill in the art based upon this disclosure. It is contemplated that various combinations or subcombinations of these specific features and aspects of embodiments may be made and still fall within the scope of the invention. Accordingly, it should be understood that various features and aspects of the disclosed embodiments can be combined with or substituted for one another in order to form varying modes of the discussed socket and heat sink unit.

What is claimed is:

1. A socket and heat sink unit configured to couple to a removable LED light module, comprising:
a socket configured to releasably couple to a removable LED light module; and
a heat sink coupleable to the socket and extending about a central axis, the heat sink portion comprising a plurality of fin members that extend outward from a central core portion, and defining one or more channels outward from the core portion and alignable with openings on the socket, the one or more channels configured to receive a fastener therein to couple the socket to the heat sink.

2. The unit of claim 1, wherein at least one or the one or more channels is defined between adjacent fin members at the junction of the fin members to the central core portion.

3. The unit of claim 1, wherein at least one or the one or more channels is defined independent of any of the fins of the heat sink unit.

4. The unit of claim 1, wherein at least one of the one or more channels is defined at a distal end of one of the plurality of fin members.

5. The unit of claim 1, wherein the one or more channels have a generally “C” shaped cross-section.

6. The unit of claim 1, wherein the heat sink has a generally cylindrical shape.

7. The unit of claim 1, wherein the heat sink has a generally domed shape.

8. The unit of claim 1, wherein the channel extends along the entire length of the heat sink.

9. The unit of claim 1, wherein the fastener is a self-tapping screw.

10. The unit of claim 1, wherein the heat sink is formed via an extrusion process.

11. The unit of claim 10, wherein the extrusion process forms the one or more channels in the heat sink that are configured to receive one or more fasteners therein.

12. The unit of claim 1, wherein the fin members curve in a clockwise direction.

13. The unit of claim 1, wherein the socket has an opening that extends entirely through the socket, such that a bottom surface of the LED light module resiliently contacts a top surface of the central core portion of the heat sink when the LED light module is coupled to the socket and heat sink unit.

14. A method for making a socket and heat sink unit coupleable to a removable LED light module, comprising:
extruding a heat sink portion extending about a central axis, the heat sink portion comprising a plurality of fin members that extend outward from a central core portion, the heat sink portion further comprising one or more channels outward from the core portion and configured to receive one or more fasteners therein;
forming a socket portion having one or more openings alignable with the one or more channels in the heat sink portion for receiving the one or more fasteners therethrough, the socket configured to releasably couple to a removable LED light module; and
coupling the socket portion to the heat sink portion with the one or more fasteners.

15. The method of claim 14, wherein at least one or the one or more channels is defined between adjacent fin members at the junction of the fin members to the central core portion.

16. The method of claim 14, wherein at least one or the one or more channels is defined independent of any of the fins of the heat sink unit.

17. The method of claim 14, wherein at least one of the one or more channels is defined at a distal end of one of the plurality of fin members.

18. The method of claim 14, wherein the one or more channels have a generally “C” shaped cross-section.

19. The method of claim 14, wherein the heat sink portion has a generally cylindrical shape.

20. The method of claim 14, wherein the heat sink portion has a generally domed shape.

21. The method of claim 14, wherein the channel extends along the entire length of the heat sink portion.

22. The method of claim 14, wherein the fastener is a self-tapping screw.

23. The method of claim 14, wherein the fin members curve in a clockwise direction.

24. The method of claim 14, further comprising coupling an LED light module to the socket such that a bottom surface of the LED light module resiliently contacts a top surface of the central core portion of the heat sink.

25. A method for making a socket and heat sink unit coupleable to a removable LED light module, comprising:
extruding a heat sink portion extending about a central axis, the heat sink portion comprising a plurality of fin members that extend outward from a central core portion, said extrusion forming one or more fastener holes in the heat sink portion configured to receive one or more fasteners therein;
forming a socket portion having at least one opening for receiving the one or more fasteners therethrough, the socket configured to releasably couple to a removable LED light module; and
coupling the socket portion to the heat sink portion with the one or more fasteners.

26. The method of claim 25, wherein at least one of the one or more fastener holes is formed proximate the central core portion of the heat sink portion.
